(19) United States
(12) Patent Application Publication
(10) Pub. No.: US 2019/0096944 A1
(43) Pub. Date: Mar. 28, 2019

(54) SOLID-STATE IMAGE PICKUP DEVICE AND MANUFACTURING METHOD OF THE SAME

(71) Applicant: SHARP KABUSHIKI KAISHA, Sakai City (JP)

(72) Inventors: FUMINORI OKADA, Sakai City (JP); OSAMU YANAGIDA, Sakai City (JP)

(21) Appl. No.: 16/147,382

(22) Filed: Sep. 28, 2018

(30) Foreign Application Priority Data
Sep. 28, 2017 (JP) 2017-189056

(51) Int. Cl. H01L 27/146

(52) U.S. Cl. CPC H01L 27/14625; H01L 27/14683; H01L 27/14636

(57) ABSTRACT

First bumps and second bumps are arranged on a substrate. Top surfaces in a desired positional relationship are formed by pressing the bumps by a pressing member at the same time. An image pickup element is bonded to the first bumps and a sensor cover is bonded to the second bumps.

### BACKGROUND

### 1. Field

The present disclosure relates to a solid-state image pickup device and a manufacturing method thereof.

### 2. Description of the Related Art

Conventionally, in a manufacturing method of a solid-state image pickup device such as a camera module, when mounting an image pickup element, a sensor cover, and the like over a substrate, positions of the substrate and each connection component such as the image pickup element may vary with respect to their designed positions. This variation may be a cause of misalignment between a lens and the image pickup element in the camera module and may cause a seriously negative impact on quality of the camera module. As a countermeasure against this problem, for example, a method is known where the variation is suppressed by creating a reference surface over the substrate by using a resist, determining a bonding position of the image pickup element and the like based on the reference surface, and bonding the image pickup element and the like to the substrate (for example, see Japanese Unexamined Patent Application Publication No. 2017-11217 (disclosed on Jan. 12, 2017)).

In recent years, a camera module mounted in an information terminal or the like is desired to be further downsized. The more the camera module is downsized, the more a small position shift between a designed position and a mounted position generated when each component of the camera module is mounted (hereinafter referred to as a shift of mounted position) may largely affect the quality of the camera module. In particular, it is difficult to completely flatten the substrate of the camera module, so that if a small warp is generated in the substrate, the shift of mounted position is apt to occur when a component of the camera module such as an image pickup element or a sensor cover is mounted over the substrate. Therefore, the warp of the substrate may largely affect the quality of the camera module.

The conventional technique described above is based on a fact that the substrate is flat. Therefore, when the substrate is warped, the reference surface may not be flat. As a result, the quality of the camera module may be largely affected.

### SUMMARY

It is desirable to provide a solid-state image pickup device and a manufacturing method thereof, which can easily suppress influence on the quality due to the warp of the substrate.

According to a first aspect of the disclosure, there is provided a manufacturing method of a solid-state image pickup device, including a first process of arranging first bumps in positions on a substrate for supporting an image pickup element and arranging second bumps in positions on the substrate for supporting an optical element support member for supporting an optical element on an optical axis of the image pickup element, a second process of forming top surfaces on the first bumps and the second bumps by pressing the first bumps and the second bumps from above by a pressing member having a surface shape according to a relative positional relationship between the image pickup element and the optical element support member, where the optical element is supported on an optical axis of the image pickup element, a third process of mounting the image pickup element over the substrate by bonding the image pickup element to the first bumps, and a fourth process of bonding the optical element support member to the second bumps.

According to a second aspect of toe disclosure, there is provided a solid-state image pickup device including a substrate, a plurality of first bumps and a plurality of second bumps, which are arranged on the substrate, an image pickup element mounted over the substrate by being bonded to the first bumps, and an optical element support member which is bonded to the second bumps and covers the image pickup element. Each of the first bumps and the second bumps has a top surface formed by being pressed by a pressing member at the same time.

### BRIEF DESCRIPTION OF THE DRAWINGS

FIG. 1A is a plan view schematically showing a configuration of a solid-state image pickup device according to a first embodiment of the present disclosure, FIG. 1B is a diagram schematically showing a cross section of the solid-state image pickup device taken along line IB-IB in FIG. 1A, and FIG. 1C is a diagram schematically showing a cross section of the solid-state image pickup device taken along line IC-IC in FIG. 1A;

FIGS. 2A to 2C are diagrams schematically showing essential parts of a manufacturing method of the solid-state image pickup device according to the first embodiment of the present disclosure;

FIGS. 3A to 3C are diagrams schematically showing essential parts of the manufacturing method of the solid-state image pickup device when a substrate is partially warped according to the first embodiment of the present disclosure;

FIGS. 4A to 4C are diagrams schematically showing essential parts of a manufacturing method of a solid-state image pickup device according to a second embodiment of the present disclosure; and

FIG. 5 is a cross-sectional view schematically showing a structure of a camera module having a solid-state image pickup device according to a third embodiment of the present disclosure.

### DESCRIPTION OF THE EMBODIMENTS

### First Embodiment

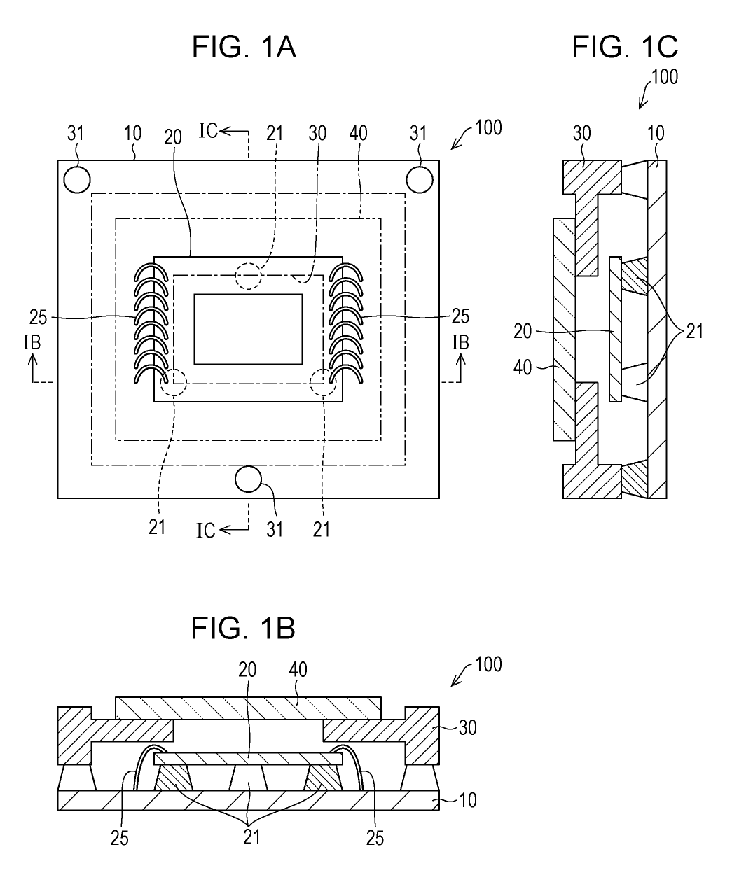

Hereinafter, an embodiment of the present disclosure will be described in detail. FIG. 1A is a plan view schematically showing a configuration of a solid-state image pickup device according to the present embodiment. FIG. 1B is a diagram schematically showing a cross section of the solid-state image pickup device taken along line IB-IB in FIG. 1A. FIG. 1C is a diagram schematically showing a cross section of the solid-state image pickup device taken along line IC-IC in FIG. 1A.

As shown in FIGS. 1A to 1C, the solid-state image pickup device 100 has a substrate 10, an image pickup element 20, a sensor cover 30, and a lid glass 40. In FIG. 1A, to illustrate the solid-state image pickup device 100 in a way easy to understand, the sensor cover 30 is shown by chain lines and the lid glass 40 is shown by a two-dot chain line.

The substrate 10 has wiring lines electrically connected to the image pickup element 20 and can support the image pickup element 20 thereon. The substrate 10 is, for example, a flexible substrate (FPC).

The image pickup element 20 is an element for picking up an image. For example, the image pickup element 20 is a CCD image sensor or the CMOS image sensor. The image pickup element 20 is arranged on a plurality of first bumps 21 and is electrically connected to the wiring lines of the substrate 10 by wires 25. The image pickup element 20 is bonded to the first bumps 21.

The first bumps 21 support the image pickup element 20. The first bump 21 is, for example, a stud bump. For example, the first bump 21 is arranged at three positions which are both end portions of one side portion (lower side with respect to the paper surface of FIG. 1A) of the image pickup element 20 and a central portion of the other side portion (upper side with respect to the paper surface of FIG. 1A). For example, the first bumps 21 are arranged at positions that are in contact with neither the wiring lines of the substrate 10 nor electronic circuits of the image pickup element 20.

The sensor cover 30 is a member that covers the image pickup element 20 over the substrate 10 from above. The sensor cover 30 has, for example, a rectangular top plate portion located above the image pickup element 20 and a wall surface portion extending downward from each side edge of the top plate portion. The top plate portion has an opening in its central portion. The sensor cover 30 is arranged on a plurality of second bumps 31. The sensor cover 30 is bonded to the second bumps 31 with an adhesive.

The second bumps 31 support the sensor cover 30. The second bump 31 is, for example, a stud bump. When the substrate 10 is seen in plan view, the second bumps 31 are arranged outside the first bumps 21 and, for example, arranged at three positions which are a central portion of one side portion of the sensor cover 30 and both end portions of the other side portion. For example, the second bumps 31 are arranged at positions that are not in contact with the wiring lines of the substrate 10.

The sizes and the types of materials of the first bump 21 and the second bump 31 may be the same or different from each other. From a viewpoint of adjusting the heights of all the first bumps 21 and all the second bumps 31 at the same time by a pressing member described later, it is preferable that the first bumps 21 and the second bumps 31 are formed of the same type of material.

The lid glass 40 is arranged at a position where the lid glass 40 closes an opening of the sensor cover 30. The lid glass 40 is, for example, a glass plate fixed to the sensor cover 30.

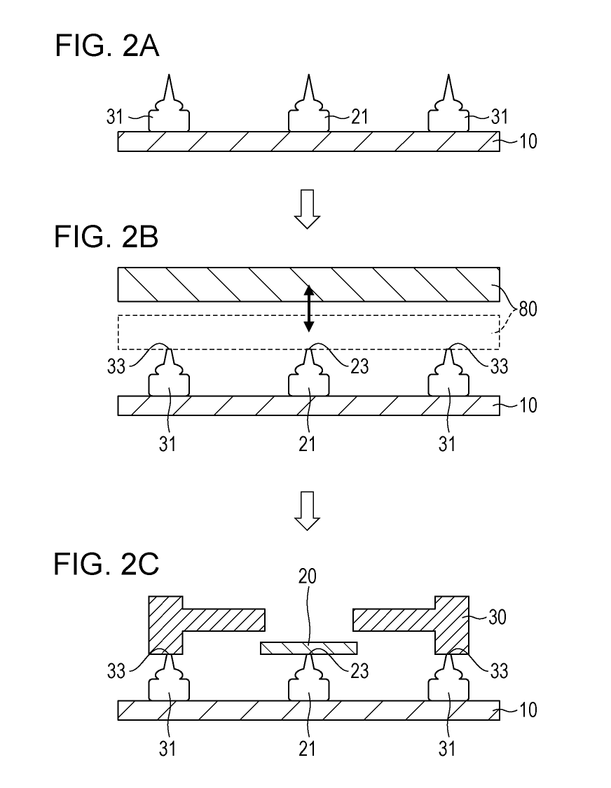

FIGS. 2A to 2C are diagrams schematically showing essential parts of a manufacturing method of the solid-state image pickup device 100. First, the first bumps 21 and the second bumps 31 are arranged on a surface of the substrate 10 (FIG. 2A). For example, the first bumps 21 are arranged at three positions described above in a central portion of the substrate 10 when the substrate 10 is seen in plan view. For example, the second bumps 31 are arranged at three positions described above outside the first bumps 21 (on a peripheral portion of the substrate 10 when the substrate 10 is seen in plan view). In this way, the first bumps 21 are arranged at positions for supporting the image pickup element 20 described above, and the second bumps 31 are arranged at positions for supporting the sensor cover 30 described above. The first bumps 21 and the second bumps 31 can be arranged on the substrate 10 by a well-known ball bonding method.

Next, all of the first bumps 21 and the second bumps 31 are pressed from above at the same time by a pressing member 80 (FIG. 2B). The pressing member 80 is a member having a horizontal pressing surface. The pressing member 80 is, for example, heated. Thereby, the temperature of the pressing member 80 is adjusted to an appropriate temperature which is lower than the melting points of metal materials of the first bumps 21 and the second bumps 31 and at which the metal materials are moderately softened. The pressing of the first bumps 21 and the second bumps 31 by the pressing member 80 can be performed by using a publicly known method, for example, using a leveling tool of a bump bonder. As a result, it is possible to uniform the heights of the first bumps 21 and the second bumps 31.

By the pressing by the pressing member 80, top surfaces 23 of all the first bumps 21 and top surfaces 33 of all the second bumps 31 are located in the same plane. In this way, by the pressing by the pressing member 80, the heights of the first bumps 21 and the second bumps 31 are adjusted at the same time by the same reference surface (the pressing surface described above).

Next, after an adhesive is applied to the top surfaces 23 of the first bumps 21 whose heights are adjusted, the image pickup element 20 is mounted on the first bumps 21 (FIG. 2C), and the image pickup element 20 is bonded to each first bump 21. As the adhesive, it is possible to use a publicly known resin-based adhesive such as a curable epoxy resin.

When the adhesive is being cured, the image pickup element 20 may be pressed toward the substrate 10 within a range where the first bumps 21 are not deformed. The image pickup element 20 may be subjected to another process to be electrically connected to the substrate 10. For example, the image pickup element 20 may be electrically connected to the substrate 10 by wire bonding as needed. The image pickup element 20 is mounted over the substrate 10 by the bonding and the electrical connection as described above.

Next, after the adhesive is applied to the top surfaces 33 of the second bumps 31 whose heights are also adjusted, the sensor cover 30 is mounted on the second bumps 31 (FIG. 2C), and the sensor cover 30 is bonded to each second bump 31. When the adhesive is being cured, the sensor cover 30 may be pressed toward the substrate 10 within a range where the second bumps 31 are not deformed. In this way, the image pickup element 20 and the sensor cover 30 are supported on the same virtual plane above the substrate 10 by the first bumps 21 and the second bumps 31, respectively.

The manufacturing method of the solid-state image pickup device 100 may further include other processes other than the processes described above within a range where relative fixed positions of the image pickup element 20 and the sensor cover 30 can be maintained. Examples of the other processes include a process for arranging the lid glass 40 on the opening of the sensor cover 30.

The sensor cover 30 is designed to support an optical element to be arranged on the same optical axis as that of the image pickup element 20 on the same axis as the optical axis of the image pickup element 20 when the sensor cover 30 is supported on the same plane as the image pickup element 20. In the solid-state image pickup device 100, the first bumps 21 that support the image pickup element 20 and the second bumps 31 that support the sensor cover 30 are pressed at the same time by the pressing member 80 that has a horizontal pressing surface. Therefore, the top surfaces 23 of the first bumps 21 and the top surfaces 33 of the second bumps 31 are located in the same plane. Thus, the optical element described above is supported and fixed on the same axis as the optical axis of the image pickup element 20 by the sensor cover 30.

In this way, the sensor cover 30 indirectly supports the optical element so that the optical axis of the optical element is the same as the optical axis of the image pickup element 20, so that the sensor cover 30 corresponds to an optical element support member for supporting the optical element arranged on the optical axis of the image pickup element. Examples of the optical element include a mirror, a lens, a prism, and a filter.

In the solid-state image pickup device 100 manufactured in this way, the top surfaces 23 of the first bumps 21 and the top surfaces 33 of the second bumps 31 are formed at the same time by pressing from the integrated pressing member 80. Therefore, on all the top surfaces 23 and 33, a substantially uniform adhesive layer (for example, an adhesive layer having a substantially constant thickness) is formed along the top surface. In more detail, the adhesives applied to the top surfaces are pressed against the image pickup element 20 and the sensor cover 30, so that the adhesives spread on the top surfaces and bond the image pickup element 20 and the sensor cover 30 to the first bumps 21 and the second bumps 31, respectively. Thus, the uniform adhesive layer is formed on the top surfaces.

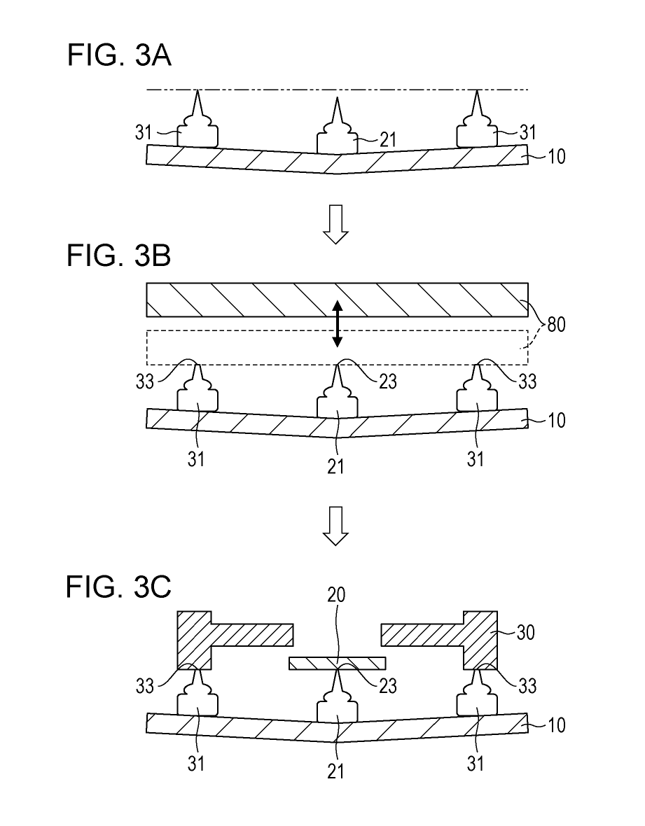

FIGS. 3A to 3C are diagrams schematically showing essential parts of the manufacturing method of the solid-state image pickup device 100 when the substrate 10 is partially warped.

First, in the same manner as the aforementioned manufacturing method shown in FIGS. 2A to 2C, the first bumps 21 and the second bumps 31 are arranged on the surface of the substrate 10 (FIG. 3A). For example, as shown in FIGS. 3A to 3C, the substrate 10 is partially warped so that a central portion of the substrate 10 is recessed from above. Therefore, when bumps having the same height are arranged as the first bumps 21 and the second bumps 31, the heights of the first bumps 21 are lower than those of the second bumps 31. The two-dot chain line in FIG. 3A is a virtual horizontal reference line.

Next, all of the first bumps 21 and the second bumps 31 are pressed from above at the same time by the pressing member 80 (FIG. 3B). Although the height of the first bump 21 and the height of the second bumps 31 are different from each other, the pressing member 80 presses all the bumps to sufficient depths where all the bumps are pressed. By this pressing, the higher the bump (the second bump 31 in FIGS. 3A to 3C), the more the bump is crushed, and the lower the bump (the first bump 21 in FIGS. 3A to 3C), the less the bump is crushed. In this way, the top surfaces 23 of the first bumps 21 and the top surfaces 33 of the second bumps 31 are located in the same plane.

Next, the image pickup element 20 is mounted to the substrate 10 by bonding the image pickup element 20 to the first bumps 21 whose heights are adjusted. Further, the sensor cover 30 is bonded to the second bumps 31 whose heights are also adjusted (FIG. 3C). In the same manner as the aforementioned manufacturing method, the image pickup element 20 and the sensor cover 30 are supported on the same virtual plane above the warped substrate 10 by the first bumps 21 and the second bumps 31.

As described above, the manufacturing method described above can support the image pickup element 20 and the sensor cover 30 on the same plane regardless of the presence or absence of the warp of the substrate 10.

The manufacturing method described above uses a plurality of first bumps 21 and a plurality of second bumps 31 located on the substrate 10 and arranges the top surfaces of these bumps in the same plane used as a reference plane regardless of the presence or absence of the warp of the substrate 10 by pressing the bumps at the same time by using the integrated pressing member 80. Therefore, a relative positional relationship between the image pickup element 20 and the sensor cover 30 according to a design is easily realized regardless of the presence or absence of the warp of the substrate 10.

### Second Embodiment

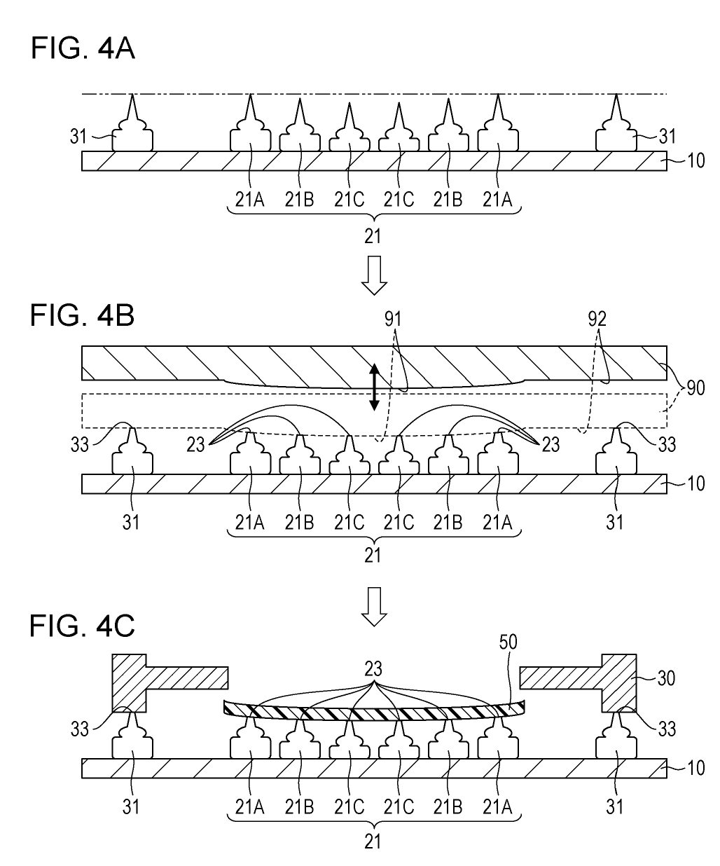

Another embodiment of the present disclosure will be described below. For convenience of description, members having the same functions as those of the members described in the above embodiment will be denoted by the same reference numerals and the description thereof will be omitted. In the present embodiment, a manufacturing method of a solid-state image pickup device having a curved image pickup element will be described. FIGS. 4A to 4C are diagrams schematically showing essential parts of the manufacturing method of the solid-state image pickup device according to the second embodiment of the present disclosure.

First, the first bumps 21 and the second bumps 31 are arranged on the surface of the substrate 10 (FIG. 4A). The first bumps 21 are arranged at positions for supporting the image pickup element 50 described above, and the second bumps 31 are arranged at positions for supporting the sensor cover 30 described above. The first bumps 21 include bumps 21A to 21C whose heights are different from each other. Such bumps whose heights are different from each other can be formed by a publicly known technique such as, for example, a technique described in Japanese Unexamined Patent Application Publication No. 2009-049499.

The bump 21A is the highest bump among the bumps 21A to 21C and, for example, has the same height as that of the second bump 31. The bump 21A is arranged at the farthest position from the center of the image pickup element 50 among the bumps 21A to 21C and, for example, the bumps 21A are arranged at positions for supporting a peripheral portion of the image pickup element 50 (that is, the bumps 21A are arranged in a rectangular shape when the substrate 10 is seen in plan view).

The bump 21B is the second highest bump among the bumps 21A to 21C and is arranged at the second farthest position next to the bump 21A from the center of the image pickup element 50 among the bumps 21A to 21C. For example, when the substrate 10 is seen in plan view, the bumps 21B are arranged in a rectangular shape along inside of the arrangement of the bumps 21A.

The bump 21C is the lowest bump among the bumps 21A to 21C and is arranged at the closest position to the center of the image pickup element 50 among the bumps 21A to 21C. For example, the bumps 21C are arranged inside the arrangement of the bumps 21B and at positions for supporting a central portion of the image pickup element 50 (for example, the bumps 21C are arranged in a rectangular shape when the substrate 10 is seen in plan view).

The second bumps 31 are arranged outside the first bumps 21A and at positions supporting the sensor cover 30, for example, the second bumps 31 are arranged at the three positions described above. The two-dot chain line in FIG. 4A is a virtual horizontal reference line.

Next, all of the first bumps 21 and the second bumps 31 are pressed from above at the same time by a pressing member 90 (FIG. 4B). The pressing member 90 includes a convex surface portion 91 and a flat surface portion 92 arranged around the convex surface portion 91. The convex surface portion 91 is a portion having a convex curved surface where the image pickup element 50 that is curved and supported comes into contact with the first bumps 21. The convex surface portion 91 has the same shape as that obtained by seeing the image pickup element 50 in plan view (for example, a rectangular shape). The flat surface portion 92 is a portion having a flat plane surface with which the sensor cover 30 comes into contact. The flat surface portion 92 has a rectangular frame shape surrounding the convex surface portion 91 when seen in plan view. Both the convex surface portion 91 and the flat surface portion 92 are pressing surfaces.

By the pressing by the pressing member 90, all the first bumps 21 (the bumps 21A to 21C) are pressed by the convex surface portion 91 and all the second bumps 31 are pressed by the flat surface portion 92. The pressing of these bumps is performed at the same time. By this pressing, the top surfaces 23 of all the first bumps 21 are located in an expected concave curved surface and the top surfaces 33 of all the second bumps 31 are located in a flat plane surface. A relative positional relationship between the concave curved surface and the flat plane surface is maintained to a relative positional relationship between the convex surface portion 91 and the flat surface portion 92. In this way, by the pressing by he pressing member 90, the heights of the first bumps 21 and the heights of the second bumps 31 are adjusted at the same time by the same reference surface (the pressing surfaces described above) even when the heights of the first bump 21 and the heights of the second bumps 31 are located in different surfaces.

Next, the image pickup element 50 is mounted on the first bumps 21 whose heights are adjusted and the sensor cover 30 is mounted on the second bumps 31 whose heights are also adjusted (FIG. 4C).

The image pickup element 50 is an image pickup element that is arranged on the substrate 10 so as to be curved and recessed from above. For example, the image pickup element 50 has flexibility. The image pickup element 50 is pressed downward against the top surfaces 23 of all the first bumps 21 by a publicly known method and bonded and fixed to the top surfaces 23 of all the first bumps 21. The pressing downward of the image pickup element 50 can be performed by a publicly known method such as blowing compressed air or pressing a tool as described in Japanese Unexamined Patent Application Publication No. 2009-049499.

Next, the sensor cover 30 is mounted on the second bumps 31. The mounting of the sensor cover 30 onto the second bumps 31 is performed in the same manner as in the first embodiment described above. In this way, the image pickup element 50 and the sensor cover 30 are supported on a virtual reference surface above the substrate 10 (the convex curved surface with respect to the substrate and the flat plane surface extending outward from the periphery of the convex curved surface) by the first bumps 21 and the second bumps 31.

Also in the manufacturing method of the present embodiment, a plurality of the first and the second bumps are arranged on the substrate and the heights of the first bumps and the second bumps are adjusted at the same time to heights for supporting the image pickup element and the sensor cover in a desired positional relationship. Therefore, according to the manufacturing method described above, it is possible to easily arrange and fix the image pickup element and he sensor cover on the substrate 10 in a positional relationship according to the design regardless of the presence or absence of warp of the substrate 10.

### Third Embodiment

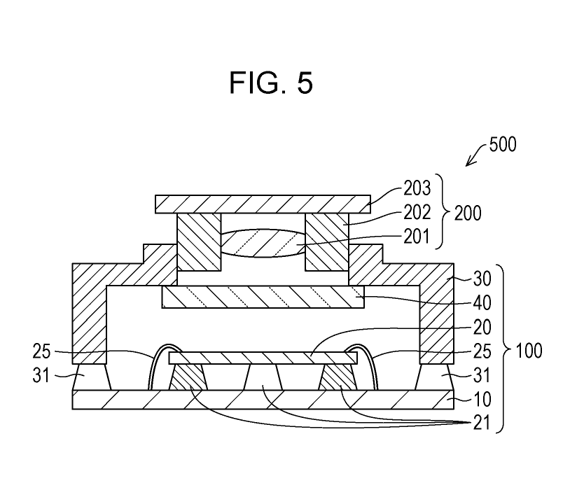

FIG. 5 is a cross-sectional view schematically showing a structure of a camera module having the solid-state image pickup device described above. As shown in FIG. 5, the camera module 500 has a solid-state image pickup device 100 and an optical unit 200.

The solid-state image pickup device 100 is, for example, a device manufactured by a manufacturing method of the embodiments described above. The sold-state image pickup device 100 includes a substrate 10, an image pickup element 20, first bumps 21, a sensor cover 30, second bumps 31, and a lid glass 40.

The optical unit 200 is held by the sensor cover 30 of the solid-state image pickup device 100. The optical unit 200 has a lens 201, a lens barrel 202 that holds the lens 201, and a lens cover 203 that covers the lens 201.

The lens 201 is held in a position having the same optical axis as that of the image pickup element 20 by the lens barrel 202. The lens barrel 202 is a cylindrical member that holds the lens 201 and is supported by the sensor cover 30 slidably along the optical axis. The lens cover 203 is arranged attachably and detachably to and from the lens barrel 202.

The sensor cover 30 holds the lens barrel 202, and the lens barrel 202 holds the lens 201. The lens 201 is arranged in a position where the optical axis of the lens 201 is the same as the optical axis of the image pickup element 20. In this way, the sensor cover 30 indirectly holds the lens 201 according to the design, that is, on the optical axis of the image pickup element 20.

As described above, the sensor cover 30 is fixed to the substrate 10 in an expected (designed) relative positional relationship with the image pickup element 20. Therefore, the lens 201 is also arranged in a position having an expected relative positional relationship with the image pickup element 20, that is, a position having the same optical axis as the optical axis of the image pickup element 20, by attaching the lens barrel 202 to the sensor cover 30. An arrangement that satisfies such an expected positional relationship is easily realized by assembling the solid state image pickup device 100 and the optical unit 200 regardless of the presence or absence of the warp of the substrate 10.

As obvious from the above description, according to the embodiment described above, it is possible to easily mount the image pickup element and the sensor cover in parallel with each other regardless of the warp of the substrate of the camera module. Further, even when mounting a curved image pickup element, it is possible to easily mount the image pickup element and the sensor cover in an expected relative positional relationship. Further, as obvious from the fact that the embodiment described above is realized by directly using or diverting existing manufacturing facilities such as a bump manufacturing device and the pressing member, the embodiment does not require an additional expensive facility, so that the embodiment is excellent in cost.

### Modified Example

In the above embodiments, both the first and the second bumps are stud bumps. However, the first and the second bumps may be publicly known bumps other than the stud bump. Examples of other bumps that can be used as the first bump and the second bump include a gold bump, other metal bumps, and a solder bump. Among them, the gold bump is preferred because the gold bump can be easily deformed.

Further, in the above embodiments, both the first and the second bumps are arranged in positions on the substrate that are not electrically connected to the substrate. However, the first and the second bumps may be electrically connected to the substrate. For example, bumps for electrically connecting to the substrate may be used as the first bumps or the second bumps.

In the above embodiments, all of the first bumps and the second bumps are formed of single bumps. However, the first bumps and the second bumps may include two or more stages of bumps (an integrated bump) which are formed by stacking and striking two or more bumps. There may be only one integrated bump or a plurality of integrated bumps among the first bumps and the second bumps. Alternatively, all the bumps may be the integrated bumps. Creation of the integrated bump (stacking and striking of bumps) can be performed by, for example, a publicly known method as described in Japanese Unexamined Patent Application Publication No. 7-221262.

In the above embodiments, the number of the first bumps and the number of the second bumps can be appropriately determined in a range where the image pickup element or the sensor cover can be supported in a desired position on the substrate. The number of the first bumps and the number of the second bumps are preferred to be three or more from a viewpoint of increasing connection strength of the image pickup element or the sensor cover to the substrate. The numbers of the bumps described above may be appropriately determined to be three or more from a viewpoint that the effect of increasing the connection strength is practically saturated or from a viewpoint of productivity.

In the above embodiments, the image pickup element and the sensor cover are bonded to the first bumps and the second bumps, respectively. However, the image pickup element and the sensor cover may be further directly bonded to the substrate with an adhesive as needed. For example, the image pickup element and the sensor cover can be directly bonded to the substrate by injecting an adhesive into a clearance gap between the image pickup element and the substrate and between the sensor cover and the substrate, and solidifying the adhesive.

In the above embodiments, a state where one part of a central portion of the substrate is recessed in shown. However, the number of parts where the substrate is warped may be one or more. Even when the substrate 10 has a plurality of warps, that is, for example, even when the substrate 10 has a corrugated plate shape, the manufacturing method described above can support and fix the image pickup element and the sensor cover on an expected surface over the substrate.

In the above embodiments, the lid glass is a glass plate. However, the lid glass may be an optical element having expected optical characteristics. For example, the lid glass may be a filter having an optical filter function that absorbs light beams having a predetermined wavelength.

The pressing surface of the pressing member may have further configurations in a range where the pressing surface has a surface shape on which an expected positional relationship between the image pickup element and the sensor cover described above is reflected. For example, the pressing surface may have a predetermined surface roughness or may be applied with release agent so as to improve release characteristics from the pressed first bumps and second bumps.

In the second embodiment described above, the image pickup element has flexibility. However, the mage pickup element only have to closely adhere to and be supported by the top surfaces of the first bumps 21 that are pressed by the convex surface portion. For example, the image pickup element may have a fixed shape having an expected curved surface.

### CONCLUSION

A manufacturing method of a solid-state image pickup device according to an aspect 1 of the present disclosure includes a first process of arranging first bumps in positions on a substrate for supporting an image pickup element and arranging second bumps in post ions on the substrate for supporting an optical element support member, a second process of pressing all of the first bumps and the second bumps from above by a pressing member having a surface shape according to a relative positional relationship between the image pickup element and the optical element support member and simultaneously adjusting heights of the first bumps and the second bumps to heights at which top surfaces of the first bumps and the second bumps support the image pickup element and the optical element support member in the relative positional relationship described above, a third process of mounting the image pickup element over the substrate by bonding the image pickup element to the first bumps, and a fourth process of bonding the optical element support member to the second bumps.

According to the above configuration, the pressing member presses the first bumps and the second bumps, so that the top surfaces of the bumps are adjusted to positions for supporting the image pickup element and the optical element support member at a positional relationship according to a design. Therefore, according to the above configuration, it is possible to provide a solid-state image pickup device that can easily suppress influence on quality due to warp of the substrate.

In the manufacturing method of an aspect 2 of the present disclosure according to the aspect 1, the first process may include at least one of a 1A process and a 1B process, the 1A process may be a process of arranging the first bumps in positions which are vertexes of a triangle and where edge portions of the image pickup element are supported, and the 1B process may be a process of arranging the second bumps in positions which are vertexes of a triangle and where edge portions of the optical element support member are supported.

According to the above configuration, each of the image pickup element and the optical element support member can be stably supported by a minimum number of bumps. Therefore, the above configuration is furthermore effective from a viewpoint that the image pickup element and the optical element support member are easily supported at desired positions by the first bumps and the second bumps, respectively.

In the manufacturing method of an aspect 3 of the present disclosure according to the aspect 1 or 2, the pressing member may have a convex curved surface that comes into contact with the first bumps, and the image pickup element may be mounted on the first bumps so that the image pickup element has a shape recessed upward along the convex curved surface on the first bumps pressed by the convex curved surface.

According to the above configuration, the top surfaces of the first bumps are formed in positions supporting the image pickup element supported in a shape recessed frontward over the substrate. Therefore, the above configuration is more effective from a viewpoint that the image pickup element is more easily supported in a desired relative positional relationship with the optical element support member.

In the manufacturing method of an aspect 4 of the present disclosure according to the aspect 3, in the first process, the closer the post ion supporting the image pickup element is to a center of the image pickup element, the lower the height of the first bump arranged on the substrate may be.

According to the above configuration, it is possible to press the first bumps for supporting the image pickup element that is supported in a shape recessed frontward over the substrate by substantially the same pressing distance for all the first bumps. Therefore, the above configuration is furthermore effective from a viewpoint that the image pickup element that is supported in a shape recessed frontward is more easily supported in a desired relative positional relationship with the optical element support member.

In the manufacturing method of an aspect 5 of the present disclosure according to the aspects 1 to 4, the first process may include a process of forming an integrated bump where two or more bumps are stacked in the height direction of the bumps as at least one of the first bumps and the second bumps.

The above configuration is furthermore effective from a viewpoint that the bumps whose heights are different are easily created.

In the manufacturing method of an aspect 6 of the present disclosure according to the aspects 1 to 5, the optical element support member may include a sensor cover.

A solid-state image pickup device according to an aspect 7 of the present disclosure includes a substrate, a plurality of first bumps and a plurality of second bumps, which are arranged on the substrate, an image pickup element mounted over the substrate by being bonded to the first bumps, and an optical element support member which is bonded to the second bumps and covers the image pickup element. Each of the first bumps and the second bumps has a top surface formed by being pressed by a pressing member at the same time.

According to the above configuration, the image pickup element and the optical element support member are supported by the first bumps and the second bumps in a positional relationship according to their design, so that it is possible to easily suppress influence on quality due to warp of the substrate in the solid-state image pickup device.

In the solid-state image pickup device of an aspect 8 of the present disclosure according to the aspect 7, the first bumps may be arranged in positions, which are vertexes of a triangle and where edge portions of the image pickup element are supported, on the substrate, and the second bumps may be arranged in positions, which are vertexes of a triangle and where edge portions of the optical element support member are supported, on the substrate.

According to the above configuration, each of the image pickup element and the optical element support member can be stably supported by a minimum number of bumps. Therefore, the above configuration is furthermore effective from a viewpoint that the image pickup element and the optical element support member are easily supported at desired positions by the first bumps and the second bumps, respectively.

In the solid-state image pickup device of an aspect 9 of the present disclosure according to the aspect 7 or 8, the first bumps may be a plurality of the first bumps whose heights are different, the closer the first bump is to a center of the image pickup element, the lower the height of the first bump may be, and the first bumps may have top surfaces pressed by the pressing member having a convex curved surface.

According to the above configuration, the image pickup element is supported by the first bumps whose top surfaces are formed in advance in positions supporting the image pickup element supported in a shape recessed frontward over the substrate. Therefore, the above configuration is furthermore effective from a viewpoint that the image pickup element is more easily supported in a desired relative positional relationship with the optical element support member.

In the solid-state image pickup device of an aspect 10 of the present disclosure according to the aspects 7 to 9, one or both of the first bump and the second bump may include an integrated bump where two or more bumps are stacked in the height direction of the bumps.

The above configuration is furthermore effective from a viewpoint that the aforementioned image pickup element that is supported in a shape recessed frontward over the substrate is more easily supported in a desired relative positional relationship with the optical element support member.

The solid-state image pickup device of an aspect 11 of the present disclosure according to the aspects 7 to 10 may be a camera module.

The present disclosure is not limited to the embodiments described above, but can be variously modified within a range described in claims. An embodiment obtained by appropriately combining technical units disclosed in different embodiments is included in a technical range of the present disclosure. Further, new technical characteristics can be formed by combining technical units disclosed in each embodiment.

The present disclosure contains subject matter related to that disclosed in Japanese Priority Patent Application JP 2017-189056 filed in the Japan Patent Office on Sep. 28, 2017, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A manufacturing method of a solid-state image pickup device, the manufacturing method comprising:
a first process of arranging first bumps in positions on a substrate for supporting an image pickup element and arranging second bumps in positions on the substrate for supporting an optical element support member for supporting an optical element on an optical axis of the image pickup element;
a second process of forming top surfaces on the first bumps and the second bumps by pressing the first bumps and the second bumps from above by a pressing member having a surface shape according to a relative positional relationship between the image pickup element and the optical element support member, where the optical element is supported on an optical axis of the image pickup element;
a third process of mounting the image pickup element over the substrate by bonding the image pickup element to the first bumps; and
a fourth process of bonding the optical element support member to the second bumps.

2. The manufacturing method of a solid-state image pickup device according to claim 1, wherein
the first process includes at least one of a 1A process and a 1B process,
the 1A process is a process of arranging the first bumps in positions which are vertexes of a triangle and where edge portions of the image pickup element are supported, and
the 1B process is a process of arranging the second bumps in positions which are vertexes of a triangle and where edge portions of the optical element support member are supported.

3. The manufacturing method of a solid-state image pickup device according to claim 1, wherein
the pressing member has a convex curved surface that comes into contact with the first bumps, and
the image pickup element is mounted on the first bumps so that the image pickup element has a shape recessed upward along the convex curved surface on the first bumps pressed by the convex curved surface.

4. The manufacturing method of a solid-state image pickup device according to claim 3, wherein
in the first process, the closer the position supporting the image pickup element is to a center of the image pickup element, the lower the height of the first bump arranged on the substrate.

5. The manufacturing method of a solid-state image pickup device according to claim 1, wherein
the first process includes a process of forming an integrated bump where two or more bumps are stacked in a height direction of the bumps as at least one of the first bumps and the second bumps.

6. The manufacturing method of a solid-state image pickup device according to claim 1, wherein
the optical element support member includes a sensor cover.

7. A solid-state image pickup device comprising:
a substrate;
a plurality of first bumps and a plurality of second bumps, which are arranged on the substrate;
an image pickup element mounted over the substrate by being bonded to the first bumps; and
an optical element support member which is bonded to the second bumps and covers the image pickup element,
wherein each of the first bumps and the second bumps has a top surface formed by being pressed by a pressing member at the same time.

8. The solid-state image pickup device according to claim 7, wherein
the first bumps are arranged in positions, which are vertexes of a triangle and where edge portions of the image pickup element are supported, on the substrate, and
the second bumps are arranged in positions, which are vertexes of a triangle and where edge portions of the optical element support member are supported, on the substrate.

9. The solid-state image pickup device according to claim 7, wherein
the first bumps are a plurality of the first bumps whose heights are different, the closer the first bump is to a center of the image pickup element, the lower the height of the first bump is, and the first bumps have top surfaces pressed by the pressing member having a convex curved surface.

10. The solid-state image pickup device according to claim 7, wherein
one or both of the first bump and the second bump include an integrated bump where two or more bumps are stacked in a height direction of the bumps.

11. The solid-state image pickup device according to claim 7, wherein
the solid-state image pickup device is a camera module.
